(19) United States
(12) Patent Application Publication
(10) Pub. No.: US 2024/0322486 A1
(43) Pub. Date: Sep. 26, 2024

(54) ENGAGEMENT STRUCTURE AND ENGAGEMENT METHOD FOR THE SAME

(71) Applicant: FIVEGRAND INTERNATIONAL CO., LTD., New Taipei City (TW)

(72) Inventor: TING-JUI WANG, New Taipei City (TW)

(21) Appl. No.: 18/587,991

(22) Filed: Feb. 27, 2024

(30) Foreign Application Priority Data
Mar. 23, 2023 (TW) 112110990
Sep. 21, 2023 (TW) 112136087

(51) Int. Cl. H01R 13/627

(52) U.S. Cl. CPC H01R 13/6272

(57) ABSTRACT

An engagement structure and an engagement method for the same are introduced. The engagement structure includes a body portion and a connecting portion. The connecting portion is disposed at the body portion, provided with a limiting portion, and adapted to engage with an engaged object, allowing the engaged object to be confined to a confinement range of the limiting portion. Thus, the body portion can be disposed at an object, and the connecting portion can engage with or disengage from the engaged object, allowing at least two objects to be coupled together and separated repeatedly and quickly.

### CROSS-REFERENCE TO RELATED APPLICATION

This non-provisional application claims priority under 35 U.S.C. § 119(a) on Patent Application No(s). 112110990 filed in Taiwan, R.O.C. on Mar. 23, 2023 and Patent Application No(s). 112136087 filed in Taiwan, R.O.C. on Sep. 21, 2023, the entire contents of which are hereby incorporated by reference.

### BACKGROUND OF THE INVENTION

### 1. Field of the Invention

The present disclosure relates to an engagement structure and an engagement method for the same, and in particular to an engagement structure and an engagement method for the same whereby at least two objects are coupled together and separated repeatedly and quickly.

### 2. Description of the Related Art

Conventionally, at least two objects are coupled together by fastening the at least two objects with screws.

Although the foregoing conventional way of fixation can fix and couple together at least two objects in an inseparable manner, it not only causes difficulty in assembly but also makes at least one object difficult to unfasten because the screws fix and couple together the at least two objects.

### BRIEF SUMMARY OF THE INVENTION

In at least one embodiment of the disclosure, the disclosure provides an engagement structure and an engagement method for the same whereby at least two objects are coupled together and separated repeatedly and quickly.

To achieve the above and other objectives, the disclosure provides an engagement structure comprising a body portion and at least one connecting portion. The connecting portion is disposed at the body portion. At least one side of the connecting portion has a limiting portion. The connecting portion engages with an engaged object, confining the engaged object to a confinement range of the limiting portion.

The disclosure provides another engagement method for an engagement structure, wherein the connecting portion confines the engaged object to the confinement range of the limiting portion.

The disclosure provides another engagement method for an engagement structure, wherein the connecting portion is lifted and then rotatably engages with the engaged object, or the connecting portion rotatably engages with the engaged object, or the connecting portion is resiliently lifted and then rotatably engages with the engaged object, or the connecting portion is lifted and then engages with the engaged object, or the connecting portion is lifted and then laterally engages with the engaged object.

The disclosure provides another engagement method for an engagement structure, wherein the engaged object is fitted to the connector and then engages with the connecting portion, or the engaged object is laterally fitted to the connector and then engages with the connecting portion, or the engaged object is laterally fitted to the connector and then laterally engages with the connecting portion, or the engaged object is rotatably fitted to the connector and then laterally engages with the connecting portion, or the engaged object is rotatably fitted to the connector and then rotatably engages with the connecting portion, or the engaged object is laterally fitted to the connector and then rotatably engages with the connecting portion, or the engaged object is hot-plugged into the connector and then engages with the connecting portion, or the engaged object engages with the connecting portion and then is connected to or hot-plugged into the connector, or the engaged object engages with the connecting portion, and then a user applies a force to the connecting portion or the engaged object, allowing the engaged object to be connected to or hot-plugged into the connector.

The disclosure provides another engagement method for an engagement structure, wherein the body portion has a shoulder portion adapted to abut against or to be pressed against such that a raw material of an object flows into or enters a material admission portion of a fitting portion of the body portion, or the shoulder portion is adapted to abut against or to be pressed against such that the raw material of the object snap-engages with the fitting portion to allow the body portion to be expandedly connected to the object, or allow the body portion to be soldered to the object, or allow the body portion to be fastened to the object.

The disclosure provides another engagement method for an engagement structure, wherein the body portion or the connecting portion has an accommodating portion for accommodating the engaged object not position-restrained, or accommodating the engaged object position-restrained, or accommodating the limiting portion, or accommodating the limiting portion passing through the engaged object, or accommodating the connecting portion, or accommodating the connecting portion passing through the engaged object, or the connecting portion has an accommodating portion for accommodating a corresponding structure of the body portion, or the body portion or the connecting portion has a movement space, or the connecting portion or the body portion has a movement portion, or the movement portion undergoes lateral or axial movement within the movement space, or the limiting portion undergoes axial movement or lateral movement, confining the engaged object to a confinement range of the limiting portion.

The disclosure provides another engagement method for an engagement structure, wherein the connecting portion has an engaging portion adapted to snap-engage with the body portion to allow the connecting portion to be located at a position at which the connecting portion can engage with the engaged object, or the engaging portion snap-engages with the body portion to allow the connecting portion to be located at a position at which the connecting portion cannot engage with the engaged object.

The disclosure provides another engagement method for an engagement structure, the engagement structure comprising a body portion and at least one connecting portion, the connecting portion being disposed at the body portion, having a limiting portion, and being adapted to engage with an engaged object, wherein the connecting portion is lifted and then rotatably engages with the engaged object, or the connecting portion rotatably engages with the engaged object, or the connecting portion is resiliently lifted and then rotatably engages with the engaged object, or the connecting portion is lifted and then engages with the engaged object, or the connecting portion is lifted and then laterally moved to engage with the engaged object.

The disclosure provides another engagement method for an engagement structure, the engagement structure comprising a body portion and at least one connecting portion, the connecting portion being disposed at the body portion, having a limiting portion, and being adapted to engage with an engaged object, wherein the engaged object is fitted to the connector and then engages with the connecting portion, or the engaged object is laterally fitted to the connector and then engages with the connecting portion, or the engaged object is laterally fitted to the connector and then laterally engages with the connecting portion, or the engaged object is rotatably fitted to the connector and then laterally engages with the connecting portion, or the engaged object is rotatably fitted to the connector and then rotatably engages with the connecting portion, or the engaged object is laterally fitted to the connector and then rotatably engages with the connecting portion, or the engaged object is hot-plugged into the connector and then engages with the connecting portion, or the engaged object engages with the connecting portion and then is connected to or hot-plugged into the connector, or the engaged object engages with the connecting portion and then applies a force to the connecting portion or the engaged object, allowing the engaged object to be connected to or hot-plugged into the connector.

The disclosure provides another engagement method for an engagement structure, the engagement structure comprising a body portion and at least one connecting portion, the connecting portion being disposed at the body portion, having a limiting portion, and being adapted to engage with an engaged object, wherein the body portion has a shoulder portion adapted to abut against or to be pressed against or to allow a raw material of the object to flow into or enter a material admission portion of the fitting portion, or the shoulder portion is adapted to abut against or to be pressed against or to allow the raw material of the object to snap-engage with the fitting portion, or to allow the body portion to be expandedly connected to the object, or to allow the body portion to be soldered to the object, or to allow the body portion to be fastened to the object.

The disclosure provides another engagement method for an engagement structure, the engagement structure comprising a body portion and at least one connecting portion, the connecting portion being disposed at the body portion, having a limiting portion, and being adapted to engage with an engaged object, wherein the body portion or the connecting portion has an accommodating portion adapted to accommodate the engaged object not position-restrained, or accommodate the engaged object position-restrained, or accommodate the limiting portion, or accommodate the limiting portion passing through the engaged object, or accommodate the connecting portion, or accommodate the connecting portion passing through the engaged object, or the connecting portion has an accommodating portion adapted to accommodate a corresponding structure of the body portion, or the body portion or the connecting portion has a movement space, or the connecting portion or the body portion has a movement portion, or the movement portion undergoes lateral or axial movement within the movement space, or the limiting portion undergoes axial movement or lateral movement, allowing the engaged object to be confined to the confinement range of the limiting portion.

The disclosure provides another engagement method for an engagement structure, the engagement structure comprising a body portion and at least one connecting portion, the connecting portion being disposed at the body portion, having a limiting portion, and being adapted to engage with an engaged object, wherein the connecting portion has an engaging portion adapted to engage with the body portion to allow the connecting portion to be located at a position at which the connecting portion engages with the engaged object, or the engaging portion engages with the body portion to allow the connecting portion to be located at a position at which the connecting portion does not engage with the engaged object.

Optionally, the engaged object is a board card, M.2 card, E1.S card, E3.S card, NIC card, RAM, hard disk drive, storage, IC, chip, heat-dissipating object, cooling fin, CPU, GPU, heat sink, PCB or connector.

Optionally, the body portion is fitted to an object, and the object is a circuit board, connector, metallic board, server, chamber, cabinet, storage, computer or plastic board.

Optionally, a rotation-proof portion is disposed between the connecting portion and the body portion, or a rotation-proof portion is disposed between the body portion and an object.

Optionally, a resilient component is disposed between the body portion and the connecting portion and adapted to allow the connecting portion to resiliently engage with the engaged object.

Optionally, the two sides, upper side and lower side of the limiting portion are confined to the engaged object.

Optionally, the body portion and the connecting portion are movably fitted together by the engaging portion, or the body portion and the connecting portion are movably fitted together by a bolt element or a fitting element, or the body portion and the connecting portion are movably fitted together by a resilient arm disposed therebetween, or the body portion and the connecting portion are movably fitted together by a plastic engaging portion disposed therebetween.

Optionally, the body portion or the connecting portion has a guiding portion, or the guiding portion guides the resilient component, allowing the connecting portion to resiliently engage with the engaged object.

Optionally, the body portion or the connecting portion has a blocking portion, or the blocking portion blocks the resilient component between the body portion and the connecting portion, allowing the connecting portion to resiliently engage with the engaged object.

Optionally, the two sides of the engaged object snap-engage with the connecting portion, or the two sides, upper side and lower side of the engaged object snap-engage with the connecting portion, or the two sides and upper side of the engaged object snap-engage with the connecting portion, and the lower side of the engaged object rests on the body portion, or the two sides and lower side of the engaged object snap-engage with the connecting portion and place limitation thereon with the limiting portion.

Optionally, the connecting portion snap-engages with the two sides of the engaged object, or the connecting portion snap-engages with the two sides, upper side and lower side of the engaged object, or the connecting portion snap-engages with the two sides and upper side of the engaged object, or the lower side of the engaged object rests on the body portion, or the connecting portion snap-engages with the two sides and lower side of the engaged object, or the connecting portion snap-engages with the upper side and lower side of the engaged object.

Optionally, the connecting portion is in the number of one or more, each connecting portion is parallelly fixed to the body portion and moves synchronously therewith, or each connecting portion is parallelly fixed to the body portion but does not move synchronously therewith, or each connecting portion is perpendicularly fitted to the body portion and moves synchronously therewith, or each connecting portion is perpendicularly fitted to the body portion but does not move synchronously therewith, or each connecting portion is parallel to the body portion and moves synchronously therewith, or each connecting portion is not parallel to the body portion but moves rotatably, or each connecting portion is parallel to the body portion and moves rotatably.

Optionally, the limiting portion is in the number of one or more, each limiting portion is parallelly fixed to the body portion and moves synchronously therewith, or each limiting portion is parallelly fixed to the body portion but does not move synchronously therewith, or each limiting portion is perpendicularly fitted to the body portion and moves synchronously therewith, or each limiting portion is perpendicularly fitted to the body portion but does not move synchronously therewith, or each limiting portion is not parallel to the body portion but moves rotatably, or each limiting portion is parallel to the body portion and moves rotatably.

Optionally, the engaged object has a limited portion, and the limiting portion snap-engages with the limited portion, wherein the limited portion or the limiting portion is a convex portion, concave portion, slot portion, step portion, engaging portion, flat surface portion, curved surface portion, arcuate surface portion, inclined surface portion, hole portion, post element or engaging element.

Optionally, the body portion or the connecting portion has a movement space, or the connecting portion or the body portion has a movement portion, or the movement portion undergoes lateral or axial movement within the movement space, or the limiting portion undergoes axial movement or lateral movement, confining the engaged object to a confinement range of the limiting portion.

Optionally, the body portion or the connecting portion has an accommodating portion for accommodating the engaged object not position-restrained, or accommodating the engaged object position-restrained, or accommodating the limiting portion, or accommodating the limiting portion passing through the engaged object, or accommodating the connecting portion, or accommodating the connecting portion passing through the engaged object, or the connecting portion has an accommodating portion for accommodating a corresponding structure of the body portion.

Optionally, the body portion is fitted to an object by engagement, riveting, expanded connection, resilient engagement, soldering, fastening, penetrated connection, magnetic attraction or adhesion, or the body portion and the object are integrally formed, or the body portion has a fitting portion fitted to the object.

Optionally, the movement portion has a rotation-proof portion, and the rotation-proof portion prevents the rotation of the movement portion relative to a movement space of the body portion.

Optionally, the connecting portion has an operating portion, and the operating portion is adapted to operate the connecting portion.

Optionally, the body portion and the connecting portion are movably fitted together by an engaging portion disposed therebetween, or the engaging portion is a combination of a track and a rail, or the connecting portion moves, slides or undergoes position-restrained movement relative to or snap-engages with the body portion.

Optionally, the body portion has a retention portion for position-restraining and retaining the engaged object.

Optionally, the connecting portion is in the number of two or more, or each connecting portion is perpendicularly fitted to the body portion, or each connecting portion comprises a multilayer structure, or the body portion is movably fitted to each connecting portion by a track and a rail, or each connecting portion moves, slides or undergoes position-restrained movement relative to or snap-engages with the body portion.

Optionally, the lowest one of the connecting portions has a retention portion adapted to position-restrain and retain the engaged object.

Optionally, the connecting portion has an avoidance space or an avoidance region, or the avoidance space or the avoidance region is adapted to avoid or not to interfere with a raised structure of the engaged object, an electronic component of the engaged object, an IC component of the engaged object, an electrically conductive component of the engaged object or a component of the engaged object.

Optionally, the engagement structure has an earthing structure or an electrically conductive structure, or the earthing structure or the electrically conductive structure is adapted to guide or conduct an electric current of the engaged object or an object, or the earthing structure or the electrically conductive structure is a metallic leaf spring, leaf spring, engaging element, threaded element, metallic element or electrically conductive object.

Optionally, the body portion has a shoulder portion adapted to abut against or to be pressed against such that a raw material of an object flows into or enters a material admission portion of a fitting portion of the body portion, or the shoulder portion is adapted to abut against or to be pressed against such that the raw material of the object snap-engages with a fitting portion of the body portion to allow the body portion to be expandedly connected to the object.

Optionally, the body portion, the connecting portion or the object is made of a metallic material, or the body portion is made of a metallic material or plastic material having undergone heat treatment, or the body portion has higher hardness than the object, or the raw material of the object enters or flows into a material admission portion of the body portion when the body portion is riveted to the object.

Optionally, the body portion is in the number of two, one of the body portions and an object are fitted together, or one of the body portions and the other body portion are penetratedly connected or fitted together, or one of the body portions and the other body portion are penetratedly connected or fitted together so as to be fitted to or to interfere with the engaged object, or one of the body portions and the other body portion are penetratedly connected or fitted together so as to be fitted to the connecting portion or to be fitted to or bolted to the connecting portion by a fitting element, or a fitting element passes through the two body portions and the connecting portion so as to be fitted thereto.

Optionally, the connecting portion has an engaging portion adapted to snap-engage with the body portion such that the connecting portion is located at a position at which the connecting portion can engage with the engaged object, or the engaging portion is adapted to snap-engage with the body portion such that the connecting portion is located at a position at which the connecting portion cannot engage with the engaged object.

Optionally, the engaging portion is an engaging element, an engaging element having resilience, an engaging element with a resilient component, an engaging element fitted to a resilient component, or a resilient engaging element.

Optionally, the connecting portion has an abutting-pushing structure adapted to abut and push the body portion to pull the engaged object.

Optionally, the connecting portion has a restraining portion adapted to position-restrain the engaged object, or adapted to position-restrain two sides of the engaged object, or the restraining portion has a part for position-restraining the engaged object, and the part has a concave portion or convex portion, the restraining portion restrains the engaged object from above, from below and from two sides through the concave portion or the convex portion.

Optionally, the body portion or the connecting portion has a movement space, and the movement space has a restraining portion adapted to position-restrain a latch element, the limiting portion or the connecting portion at an open position or closed position, or the restraining portion is a structure or material capable of undergoing resilient deformation or displacement, or the restraining portion is a plastic material, or the connecting portion has a retraction space for allowing the restraining portion to retract and give way.

### BRIEF DESCRIPTION OF THE DRAWINGS

Accompanying drawings required for description of embodiments of the present disclosure are briefly described below, such that the embodiments of the present disclosure or the prior art can be clearly described. Obviously, the accompanying drawings described below only serve to illustrate some embodiments of the present disclosure; thus, persons skilled in the art can obtain additional accompanying drawings in accordance with the foregoing accompanying drawings without making any creative efforts.

FIG. 1 is a schematic view of the state of use of the 1st embodiment of the disclosure.

FIG. 2 is a schematic view of the state of use of the 2nd embodiment of the disclosure.

FIG. 3 is a schematic view of the 3rd embodiment of the disclosure.

FIG. 4 is a schematic view of the state of use of the 4th embodiment of the disclosure.

FIG. 5 is a schematic view of the 5th embodiment of the disclosure.

FIG. 6 is a schematic view of the 6th embodiment of the disclosure.

FIG. 7 is a schematic view of the state of use of the 7th embodiment of the disclosure.

FIG. 8 is a schematic view of the state of use of the 8th embodiment of the disclosure.

FIG. 9 is a schematic view of the state of use of the 9th embodiment of the disclosure.

FIG. 10 is a schematic view of the 10th embodiment of the disclosure.

FIG. 11 is a first schematic view of the state of use of the 10th embodiment of the disclosure.

FIG. 12 is a second schematic view of the state of use of the 10th embodiment of the disclosure.

FIG. 13 is a schematic view of the 11th embodiment of the disclosure.

FIG. 14 is a schematic view of the state of use of the 12th embodiment of the disclosure.

FIG. 15 is a schematic view of the state of use of the 13th embodiment of the disclosure.

FIG. 16 is a schematic view of the state of use of the 14th embodiment of the disclosure.

FIG. 17 is a schematic view of the state of use of the 15th embodiment of the disclosure.

FIG. 18 is a schematic view of the state of use of the 16th embodiment of the disclosure.

FIG. 19 is a schematic view of the state of use of the 17th embodiment of the disclosure.

FIG. 20 is a schematic view of the state of use of the 18th embodiment of the disclosure.

FIG. 21 is a schematic view of the state of use of the 19th embodiment of the disclosure.

FIG. 22 is a schematic view of the state of use of the 20th embodiment of the disclosure.

FIG. 23 is a first schematic view of the state of use of the 21st embodiment of the disclosure.

FIG. 24 is a second schematic view of the state of use of the 21st embodiment of the disclosure.

FIG. 25 is a schematic view of the state of use of the 22nd embodiment of the disclosure.

FIG. 26 is a schematic view of the state of use of the 23rd embodiment of the disclosure.

FIG. 27 is a schematic view of the state of use of the 24th embodiment of the disclosure.

FIG. 28 is a schematic view of the state of use of the 25th embodiment of the disclosure.

FIG. 29 is a first schematic view of the state of use of the 26th embodiment of the disclosure.

FIG. 30 is a second schematic view of the state of use of the 26th embodiment of the disclosure.

FIG. 31 is a schematic view of the state of use of the 27th embodiment of the disclosure.

FIG. 32 is a schematic view of the state of use of the 28th embodiment of the disclosure.

FIG. 33 is a schematic view of the state of use of the 29th embodiment of the disclosure.

FIG. 34 is a schematic view of the state of use of the 30th embodiment of the disclosure.

FIG. 35 is a schematic view of the state of use of the 31st embodiment of the disclosure.

FIG. 36 is a schematic view of the state of use of the 32nd embodiment of the disclosure.

FIG. 37 is a schematic view of the state of use of the 33rd embodiment of the disclosure.

FIG. 38 is a schematic view of the state of use of the 34th embodiment of the disclosure.

FIG. 39 is a schematic view of the state of use of the 35th embodiment of the disclosure.

FIG. 40 is a schematic view of the state of use of the 36th embodiment of the disclosure.

FIG. 41 is a schematic view of the state of use of the 37th embodiment of the disclosure.

FIG. 42 is a schematic view of the state of use of the 38th embodiment of the disclosure.

FIG. 43 is a first schematic view of the state of use of the 39th embodiment of the disclosure.

FIG. 44 is a second schematic view of the state of use of the 39th embodiment of the disclosure.

FIG. 45 is a third schematic view of the state of use of the 39th embodiment of the disclosure.

FIG. 46 is a schematic view of the state of use of the 40th embodiment of the disclosure.

### DETAILED DESCRIPTION OF THE INVENTION

An engagement structure in embodiments of the present disclosure is described below with reference to accompanying drawings.

The above and other technical features and advantages of the disclosure are herein illustrated with preferred embodiments, depicted with drawings, and described below. It is worth noting that directional expressions mentioned in the embodiments below, such as “upper”, “lower”, “left”, “right”, “front” or “rear”, refer to the directions depicted in accompanying drawings. Thus, the directional expressions are illustrative rather than restrictive of the disclosure. Furthermore, in the embodiments below, like components are denoted by like reference numerals.

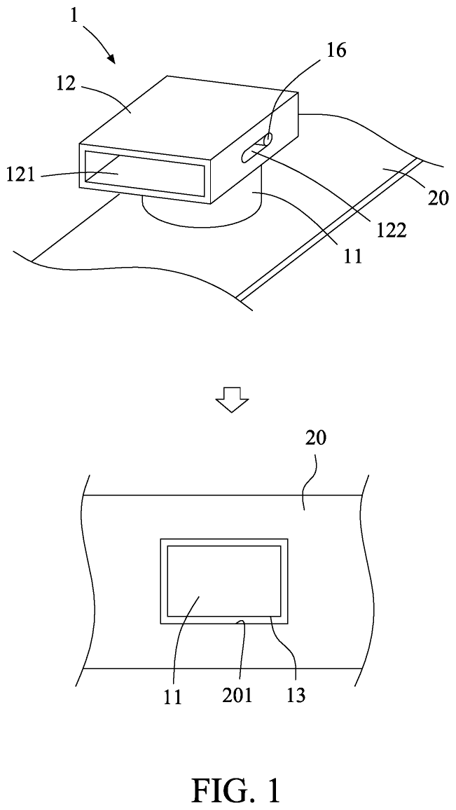

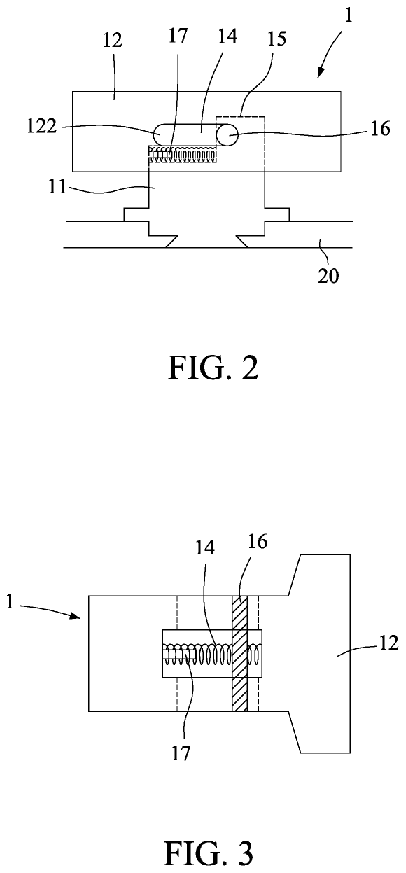

Referring to FIG. 1 through FIG. 4, the disclosure provides an engagement structure 1 and an engagement method for the same. The engagement structure 1 comprises a body portion 11 and at least one connecting portion 12.

The connecting portion 12 is movably disposed at the body portion 11. A limiting portion 121 is disposed on at least one side of the connecting portion 12. The connecting portion 12 engages with an engaged object 10 to confine the engaged object 10 to a confinement range of the limiting portion 121.

The process of fixing the engaged object 10 in place entails fitting the body portion 11 to an object 20, fitting one end of the engaged object 10 to a connector 30, and moving the connecting portion 12 to fit the other end of the engaged object 10 to the limiting portion 121 of the connecting portion 12 such that the connecting portion 12 confines the engaged object 10 to a confinement range of the limiting portion 121 to enable the connecting portion 12 to snap-engage with the two sides, upper side and lower side of the engaged object 10, so as for the two sides, upper side and lower side of the limiting portion 121 to be confined to the engaged object 10. The process of removing the engaged object 10 involves moving the connecting portion 12 to separate the other end of the engaged object 10 from the limiting portion 121 and thus cause the removal of the engaged object 10 from the connecting portion 12, allowing at least two objects to be coupled together and separated repeatedly and quickly.

In addition to the aforesaid embodiments, in an embodiment of the disclosure, the body portion 11 is fitted to the object 20 by engagement, riveting, expanded connection, resilient engagement, soldering, fastening, penetrated connection, magnetic attraction or adhesion, or the body portion 11 and the object 20 are integrally formed. Therefore, the body portion 11 is firmly fitted to the object 20 as needed.

In addition to the aforesaid embodiments, in an embodiment of the disclosure, the engaged object 10 is a board card, M.2 card, E1.S card, E3.S card, NIC card, RAM, hard disk drive, storage, IC, chip, heat-dissipating object, cooling fin, CPU, GPU, heat sink, PCB or connector, whereas the object 20 is a circuit board, connector, metallic board, server, chamber, cabinet, storage, computer or plastic board, with the connector 30 being an electrical connector of any type. Therefore, the present disclosure meets requirements for practical application.

In addition to the aforesaid embodiments, in an embodiment of the disclosure, rotation-proof portions 13, 201 are disposed between the body portion 11 and the object 20. Therefore, after the body portion 11 has been fitted to the object 20, the rotation-proof portions 13, 201 are effective in preventing rotation such that the body portion 11 is firmly fitted to the object 20 to facilitate the operation of the connecting portion 12.

In addition to the aforesaid embodiments, in an embodiment of the disclosure, a resilient component 14 is disposed between the body portion 11 and the connecting portion 12 and adapted to allow the connecting portion 12 to resiliently engage with the engaged object 10. Upon the movement of the connecting portion 12, the connecting portion 12 compresses the resilient component 14. Thus, after the other end of the engaged object 10 has been fitted to the limiting portion 121 of the connecting portion 12, the resilient component 14 is resiliently released to therefore push the connecting portion 12, confining the engaged object 10 to the confinement range of the limiting portion 121. The process of removing the engaged object 10 involves moving the connecting portion 12 to compress the resilient component 14 such that, upon separation of the other end of the engaged object 10 from the limiting portion 121 and thus removal of the engaged object 10 from the connecting portion 12, the resilient component 14 is resiliently released to therefore push the connecting portion 12 for the sake of reuse, allowing at least two objects to be coupled together and separated repeatedly and quickly.

In addition to the aforesaid embodiments, in an embodiment of the disclosure, the body portion 11 has a blocking portion 15, whereas the body portion 11 and the connecting portion 12 are movably fitted together by a bolt element 16 (or a fitting element). The bolt element 16 is penetratedly disposed at the blocking portion 15. A movement space 122 is disposed on each of the two sides of the connecting portion 12. When the connecting portion 12 moves, the bolt element 16 moves within the movement space 122.

In addition to the aforesaid embodiments, in an embodiment of the disclosure, the body portion 11 and the connecting portion 12 are movably fitted together by a resilient arm, or the body portion 11 and the connecting portion 12 are movably fitted together by a plastic engaging portion. Therefore, the present disclosure meets requirements for practical application.

In addition to the aforesaid embodiments, in an embodiment of the disclosure, the connecting portion 12 has a guiding portion 17, whereas the resilient component 14 is penetratedly disposed at the guiding portion 17. The two ends of the resilient component 14 abut against the blocking portion 15 and the connecting portion 12 respectively. The guiding portion 17 steadily guides the resilient component 14, allowing the connecting portion 12 to resiliently engage with the engaged object 10.

In addition to the aforesaid embodiments, in an embodiment of the disclosure, the rotation-proof portion 13 is disposed between the connecting portion 12 and the body portion 11 and adapted to function as a movement slot and prevent rotation such that the connecting portion 12 can undergo lateral movement relative to the body portion 11 but not rotation, so as to maintain the stability of the connecting portion 12 in motion.

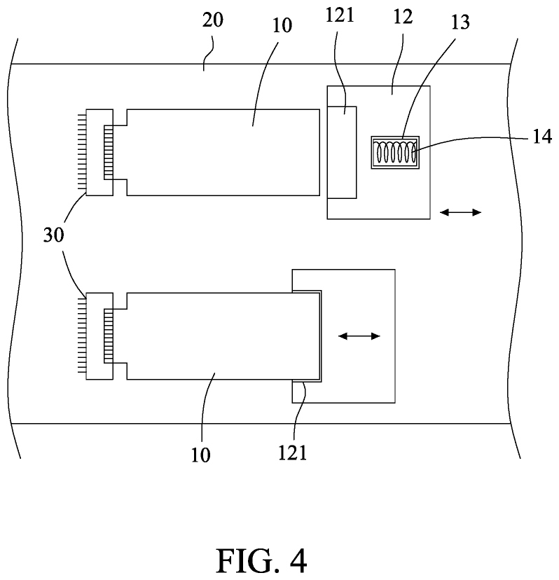

In addition to the aforesaid embodiments, in an embodiment of the disclosure, the engaged object 10 is hot-plugged into the connector 30 and then engages with the connecting portion 12 (as shown in FIG. 4). Therefore, the present disclosure meets requirements for practical application.

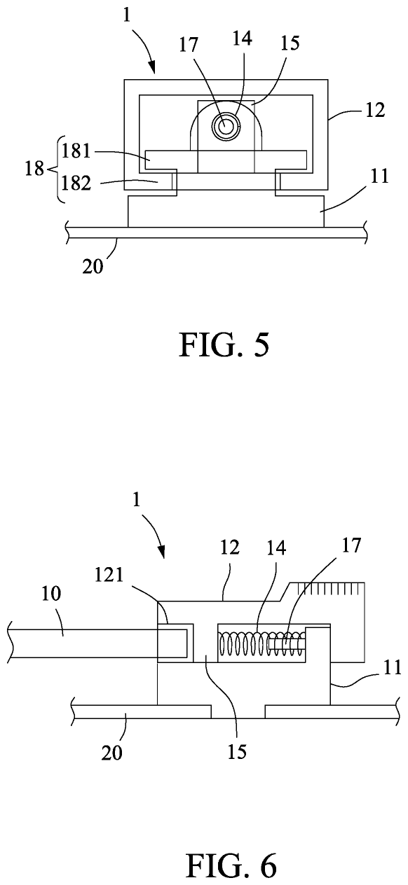

Referring to FIG. 5, in addition to the aforesaid embodiments, in an embodiment of the disclosure, the body portion 11 and the connecting portion 12 are movably fitted together by an engaging portion 18. In this embodiment, the engaging portion 18 is a combination of a track 181 and a rail 182. Therefore, the connecting portion 12 moves along the engaging portion 18 relative to the body portion 11, so as to maintain the stability of the connecting portion 12 in motion.

Referring to FIG. 6, in addition to the aforesaid embodiments, in an embodiment of the disclosure, the body portion 11 has a guiding portion 17, whereas the connecting portion 12 has a blocking portion 15. The guiding portion 17 and the blocking portion 15 correspond in position to each other. The resilient component 14 is penetratedly disposed at the guiding portion 17. The two ends of the resilient component 14 abut against the blocking portion 15 and the body portion 11 respectively. The guiding portion 17 guides the resilient component 14. The guiding portion 17 steadily guides the resilient component 14 to not only allow the connecting portion 12 to resiliently engage with the engaged object 10 but also allow the lower side of the engaged object 10 to rest on the body portion 11. Therefore, the present disclosure meets requirements for practical application.

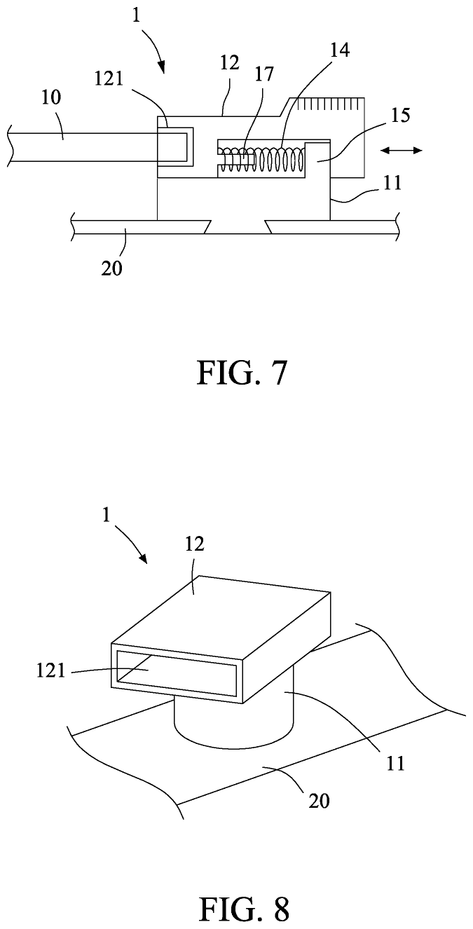

Referring to FIG. 7, in addition to the aforesaid embodiments, in an embodiment of the disclosure, the connecting portion 12 has a guiding portion 17, whereas the body portion 11 has a blocking portion 15. The guiding portion 17 and the blocking portion 15 correspond in position to each other. The resilient component 14 is penetratedly disposed at the guiding portion 17. The two ends of the resilient component 14 abut against the blocking portion 15 and the connecting portion 12 respectively. The guiding portion 17 guides the resilient component 14. The guiding portion 17 steadily guides the resilient component 14 to not only allow the connecting portion 12 to resiliently engage with the engaged object 10 but also allow the connecting portion 12 to snap-engage with the two sides, upper side and lower side of the engaged object 10 and place limitation thereon with the limiting portion 121. Therefore, the present disclosure meets requirements for practical application.

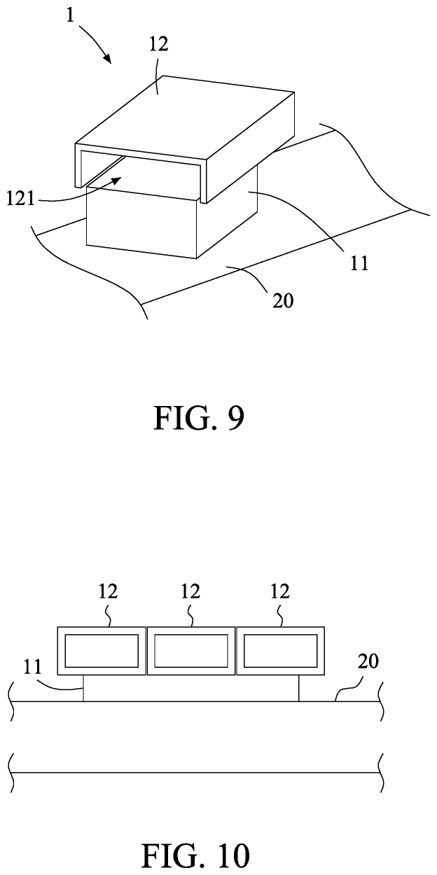

Referring to FIG. 8 and FIG. 9, in addition to the aforesaid embodiments, in an embodiment of the disclosure, the limiting portion 121 is a rectangular notch (as shown in FIG. 8) or n-shaped notch (as shown in FIG. 9). Owing to the limiting portion 121 of the connecting portion 12, the connecting portion 12 snap-engages with the two sides, upper side and lower side of the engaged object 10 and places limitation thereon with the limiting portion 121. Alternatively, the connecting portion 12 snap-engages with the two sides and upper side of the engaged object 10, and the lower side of the engaged object 10 rests on the body portion 11. Therefore, the present disclosure meets requirements for practical application.

Depending on the way of coupling the engaged object 10 and the connector 30 together, the two sides of the engaged object 10 snap-engage with the connecting portion 121, or the connecting portion 12 snap-engages with the two sides and lower side of the engaged object 10 and places limitation thereon with the limiting portion 121. Therefore, the present disclosure meets requirements for practical application.

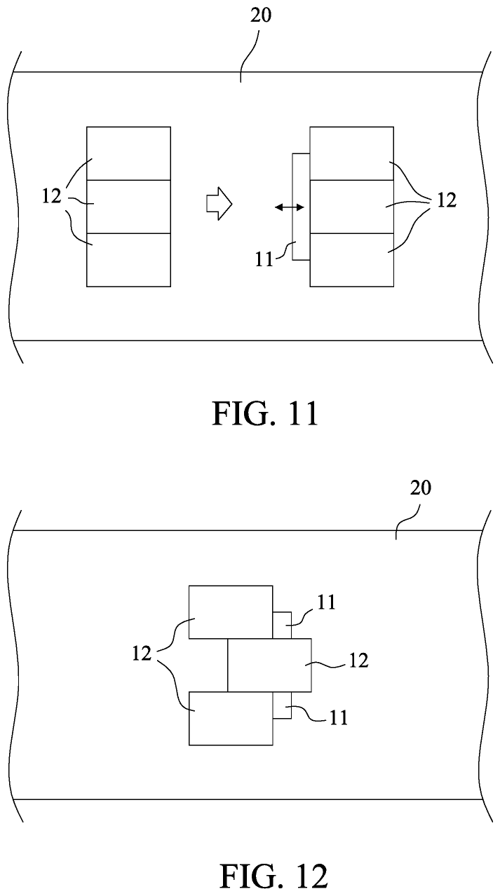

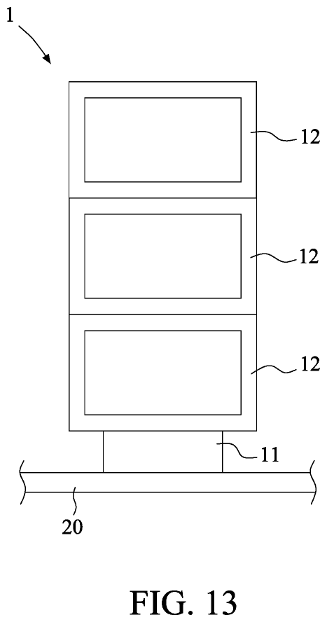

Referring to FIG. 10 through FIG. 13, in addition to the aforesaid embodiments, in an embodiment of the disclosure, the connecting portion 12 (or the limiting portion 121) is in the number of one or more, each connecting portion 12 (or each limiting portion 121) is parallelly fixed to the body portion 11 and moves synchronously therewith, or each connecting portion 12 (or each limiting portion 121) is parallelly fixed to the body portion 11 but does not move synchronously therewith (as shown in FIG. 10 through FIG. 12), or each connecting portion 12 (or each limiting portion 121) is perpendicularly fitted to the body portion 11 and moves synchronously therewith, or each connecting portion 12 (or each limiting portion 121) is perpendicularly fitted to the body portion 11 but does not move synchronously therewith (as shown in FIG. 13), or each connecting portion 12 (or each limiting portion 121) is parallel to the body portion 11 and moves synchronously therewith, allowing the connecting portion 12 to meet requirements for practical application.

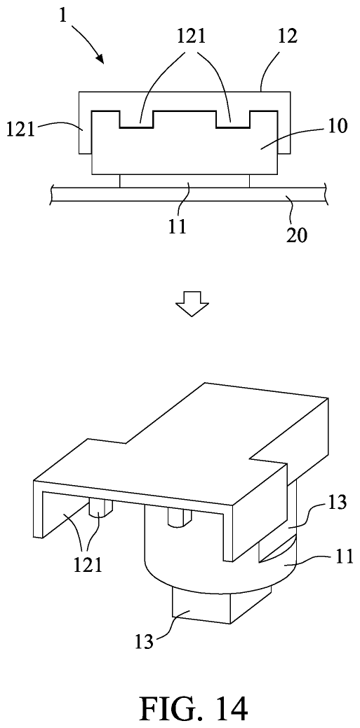

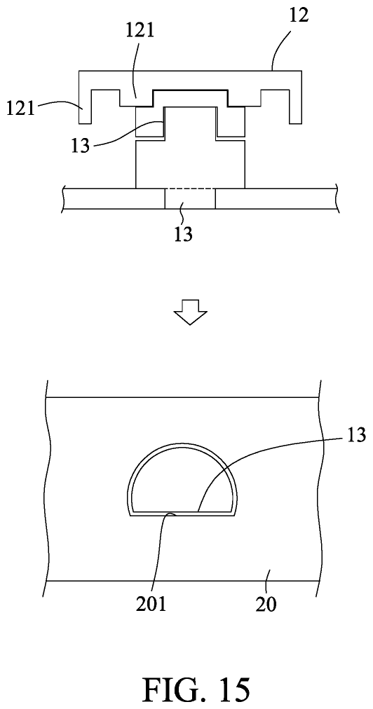

Referring to FIG. 14 and FIG. 15, in addition to the aforesaid embodiments, in an embodiment of the disclosure, the connecting portion 12 has four limiting portions 121, for example, with two limiting portions 121 disposed on the two sides of the connecting portion 12 respectively, and two other limiting portions 121 disposed between the two sides of the connecting portion 12. In this embodiment, the rotation-proof portion 13 is disposed between the connecting portion 12 and the body portion 11 and adapted to prevent rotation such that the connecting portion 12 can undergo lateral movement relative to the body portion 11 but not rotation, so as to maintain the stability of the connecting portion 12 in motion. Rotation-proof portions 13, 201 are disposed between the body portion 11 and the object 20. Therefore, after the body portion 11 has been fitted to the object 20, the rotation-proof portions 13, 201 are effective in preventing rotation such that the body portion 11 is firmly fitted to the object 20 to facilitate the operation of the connecting portion 12.

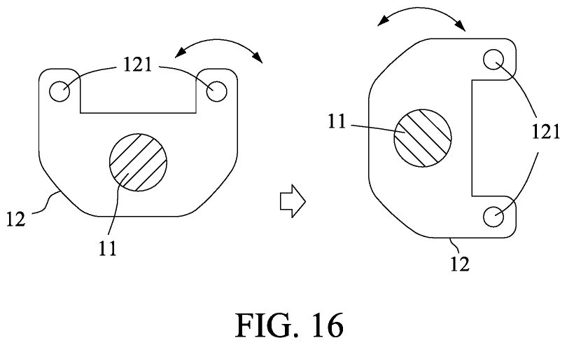

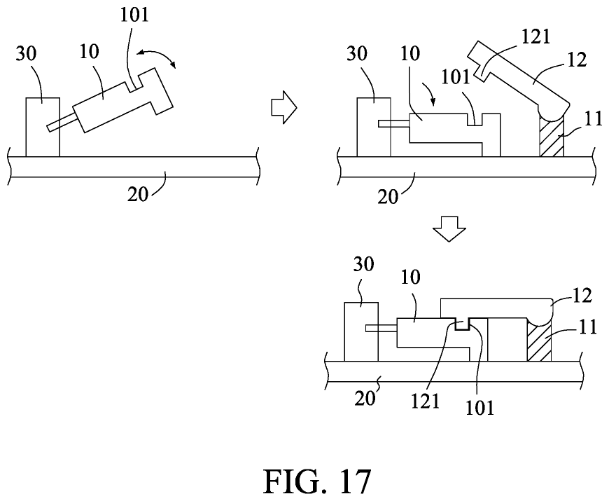

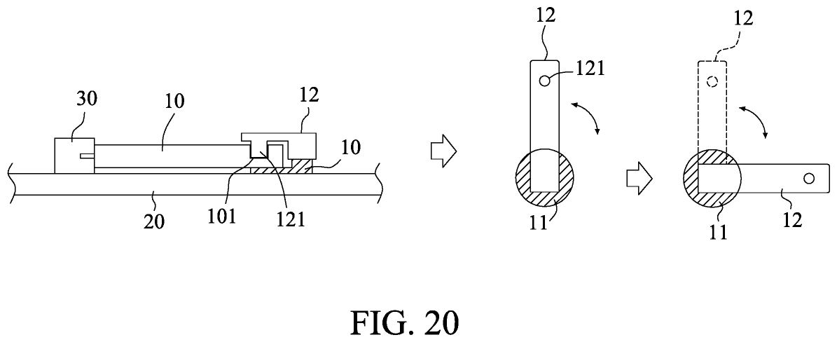

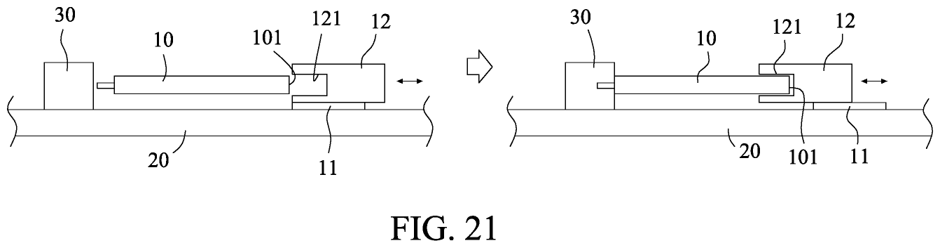

Referring to FIG. 16 through FIG. 21, in addition to the aforesaid embodiments, in an embodiment illustrated by FIG. 16 and FIG. 17, each connecting portion 12 (or each limiting portion 121) is not parallel to the body portion 11 and moves rotatably, or each connecting portion 12 (or each limiting portion 121) is parallel to the body portion 11 and moves rotatably.

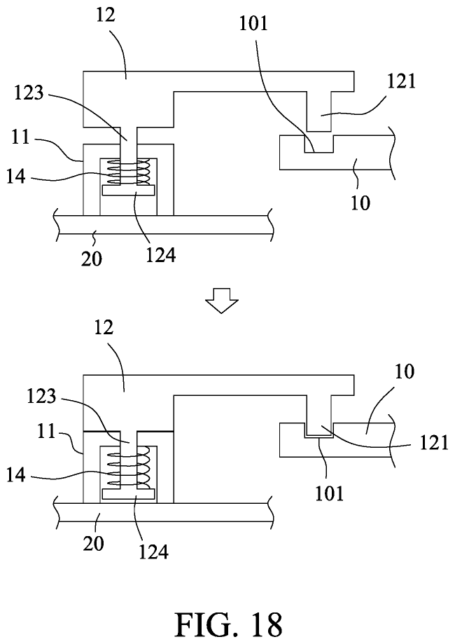

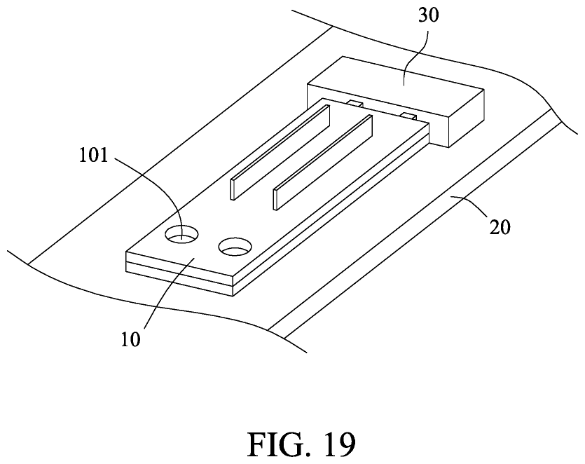

In an embodiment of an engagement method for the engagement structure 1 (as shown in FIG. 18), the resilient component 14 is fitted around a bolt element 123 of the connecting portion 12, whereas the two ends of the resilient component 14 abut against the body portion 11 and a blocking portion 124 of the connecting portion 12 respectively. The connecting portion 12 is lifted and then rotatably engages with the engaged object 10. Alternatively, the connecting portion 12 rotatably engages with the engaged object 10. Alternatively, the connecting portion 12 is resiliently lifted through the resilient component 14 and then rotatably engages with the engaged object 10. Alternatively, the connecting portion 12 is lifted and then engages with the engaged object 10. Therefore, at least two objects can be coupled together and separated repeatedly and quickly.

As shown in FIG. 19 through FIG. 21, the engaged object 10 is fitted to a connector 30 and then engages with the connecting portion 12. Alternatively, the engaged object 10 is laterally fitted to the connector 30 and then engages with the connecting portion 12. Alternatively, the engaged object 10 is laterally fitted to the connector 30 and then laterally engages with the connecting portion 12. Alternatively, the engaged object 10 is rotatably fitted to the connector 30 and then laterally engages with the connecting portion 12. Alternatively, the engaged object 10 is rotatably fitted to the connector 30 and then rotatably engages with the connecting portion 12. Alternatively, the engaged object 10 is laterally fitted to the connector 30 and then rotatably engages with the connecting portion 12. Therefore, at least two objects can be coupled together and separated repeatedly and quickly.

In addition to the aforesaid embodiments, in an embodiment of the disclosure, the engaged object 10 has a limited portion 101, and the limiting portion 121 snap-engages with the limited portion 101. The limiting portion 121 is a convex portion, concave portion, slot portion, step portion, engaging portion, flat surface portion, curved surface portion, arcuate surface portion, inclined surface portion, hole portion, post element or engaging element. Therefore, the disclosure meets requirements for practical application.

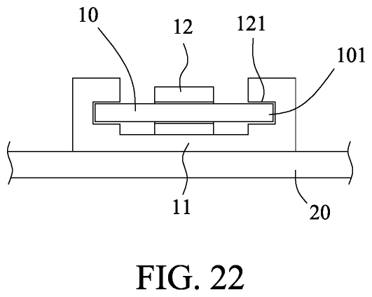

Referring to FIG. 22, in addition to the aforesaid embodiments, in an embodiment of the disclosure, the engaged object 10 has a limited portion 101, and the limiting portion 121 of the connecting portion 12 snap-engages with the limited portion 101. The limited portion 101 is a convex portion, and the limiting portion 121 is a concave portion (for example, a combination of a rail and a track). Therefore, the connecting portion 12 meets requirements for practical application.

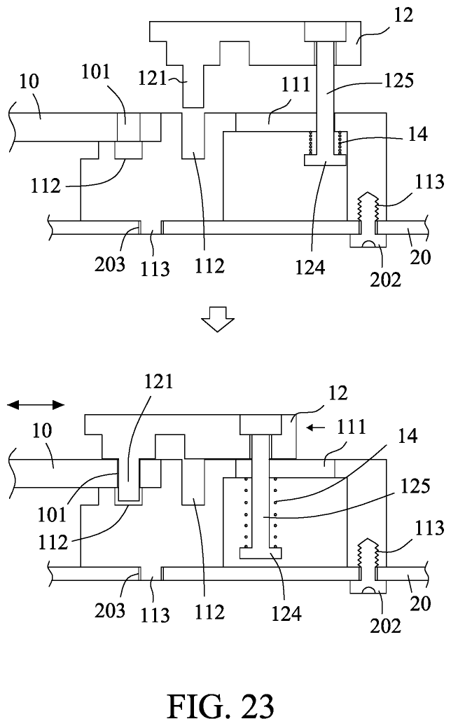

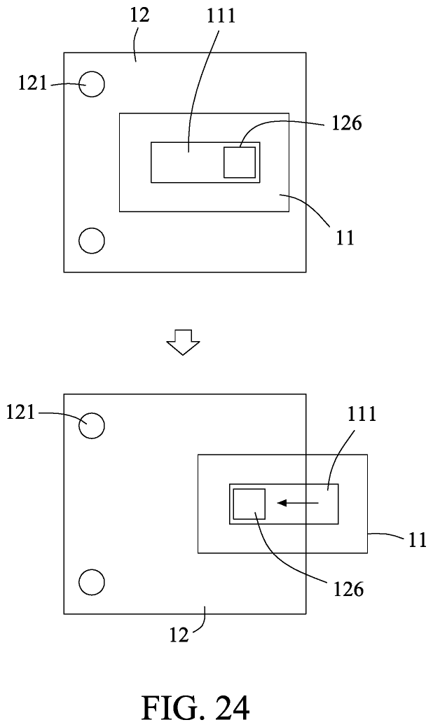

Referring to FIG. 23 and FIG. 24, in addition to the aforesaid embodiments, in an embodiment of the disclosure, the body portion 11 (or the connecting portion 12) has a movement space 111, and the connecting portion 12 (or the body portion 11) has a movement portion 125. The movement portion 125 undergoes lateral and axial movement within the movement space 111 such that the limiting portion 121 undergoes axial movement and lateral movement. As a result, the limited portion 101 of the engaged object 10 is confined to the confinement range of the limiting portion 121, for example, allowing the connecting portion 12 to snap-engage with the upper side and lower side of the engaged object 10. Therefore, at least two objects can be coupled together and separated repeatedly and quickly.

In addition to the aforesaid embodiments, in an embodiment of the disclosure, the body portion 11 has an accommodating portion 112 adapted to accommodate the engaged object 10 not position-restrained, or accommodate the engaged object 10 position-restrained, or accommodate the limiting portion 121, or accommodate the limiting portion 121 passing through the engaged object 10, or accommodate the connecting portion 12, or accommodate the connecting portion 12 passing through the engaged object 10, allowing the disclosure to meet requirements for practical application.

In addition to the aforesaid embodiments, in an embodiment of the disclosure, the movement portion 125 has a rotation-proof portion 126 adapted to prevent the rotation of the movement portion 125 relative to the movement space 111 of the body portion 11, allowing the disclosure to meet requirements for practical application.

In addition to the aforesaid embodiments, in an embodiment of the disclosure, the body portion 11 has a fitting portion 113 fitted to a fastening portion 202 of the object 20 by a means of fastening. Alternatively, the fitting portion 113 is fitted to a penetrating hole portion 203 of the object 20 by penetrated connection. Therefore, the body portion 11 and the object 20 are firmly coupled together to facilitate subsequent, related operation.

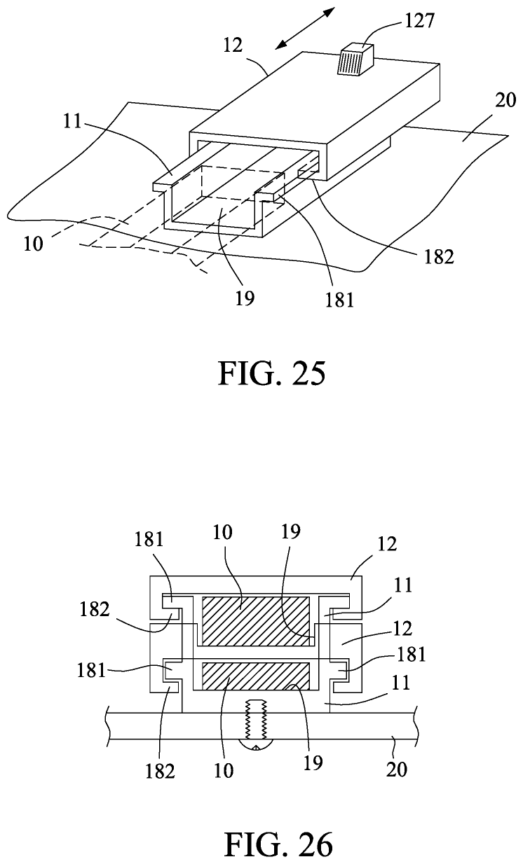

Referring to FIG. 25, in addition to the aforesaid embodiments, in an embodiment of the disclosure, the body portion 11 has a retention portion 19 adapted to position-restrain and retain the engaged object, and the connecting portion 12 has an operating portion 127. The body portion 11 and the connecting portion 12 are movably fitted together by the engaging portion 18. In this embodiment, the engaging portion 18 is a combination of a track 181 and a rail 182.

Owing to the aforesaid embodiments, the user fits the engaged object 10 to the retention portion 19 and applies a force to the operating portion 127 to not only allow the operating portion 127 to operate the connecting portion 12 but also allow the connecting portion 12 to move, slide or undergo position-restrained movement relative to or snap-engage with the body portion 11 through the combination of the track 181 and the rail 182, allowing the connecting portion 12 to position-restrain the engaged object 10.

Referring to FIG. 26, in addition to the aforesaid embodiments, in an embodiment of the disclosure, the connecting portion 12 is in the number of two or more, with each connecting portion 12 perpendicularly fitted to the body portion 11 and comprising a multilayer structure (a structure composed of layers which are on top of each other). The body portion 11 is movably fitted to each connecting portion 12 by the track 181 and the rail 182, allowing each connecting portion 12 to move, slide or undergo position-restrained movement relative to or snap-engage with the body portion 11.

In addition to the aforesaid embodiments, in an embodiment of the disclosure, the lowest one of the connecting portions 12 has the retention portion 19 adapted to position-restrain and retain the engaged object 10.

Owing to the aforesaid embodiments, the user fits two engaged objects 10 to the retention portion 19 of the body portion 11 and the retention portion 19 of the lowest one of the connecting portions 12 respectively, allowing the connecting portions 12 to position-restrain the engaged objects 10 respectively through the combination of the track 181 and the rail 182.

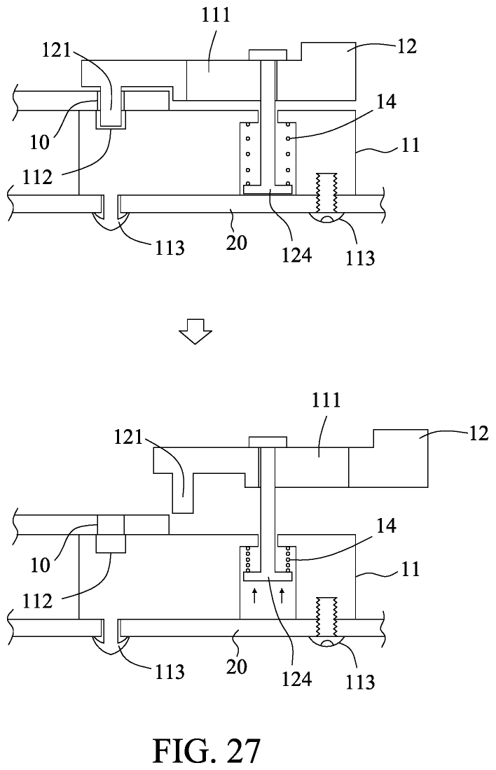

Referring to FIG. 27, in addition to the aforesaid embodiments, in an embodiment of the disclosure, the accommodating portion 112 of the body portion 11 accommodates the limiting portion 121 passing through the engaged object 10, and the connecting portion 12 has a movement space 111. The limiting portion 121 undergoes axial movement and lateral movement such that the connecting portion 12 can be lifted and then moves laterally to not only allow the limiting portion 121 to engage with the engaged object but also allow the limiting portion 121 to be accommodated in the accommodating portion 112, allowing at least two objects to be coupled together and separated repeatedly and quickly.

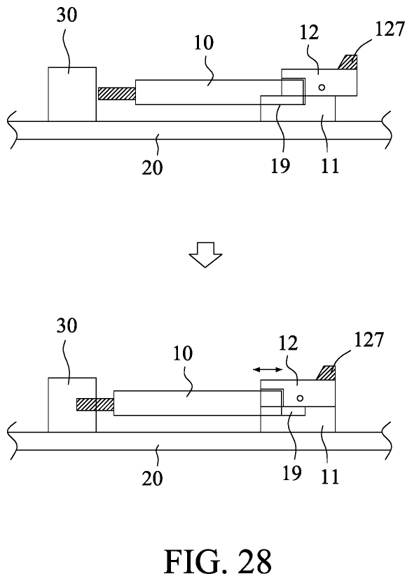

Referring to FIG. 28, in addition to the aforesaid embodiments, in an embodiment of the disclosure, after the engaged object 10 has engaged with the connecting portion 12, the engaged object 10 is connected to (or is hot-plugged into) the connector 30. To start operating the engagement structure 1, the user allows the engaged object 10 to engage with the connecting portion 12 and then applies a force to the operating portion 127 of the connecting portion 12 (or the engaged object) such that the connecting portion 12 drives the movement of the engaged object 10 to allow the engaged object 10 to be connected to or hot-plugged into the connector 30, allowing at least two objects to be coupled together and separated repeatedly and quickly.

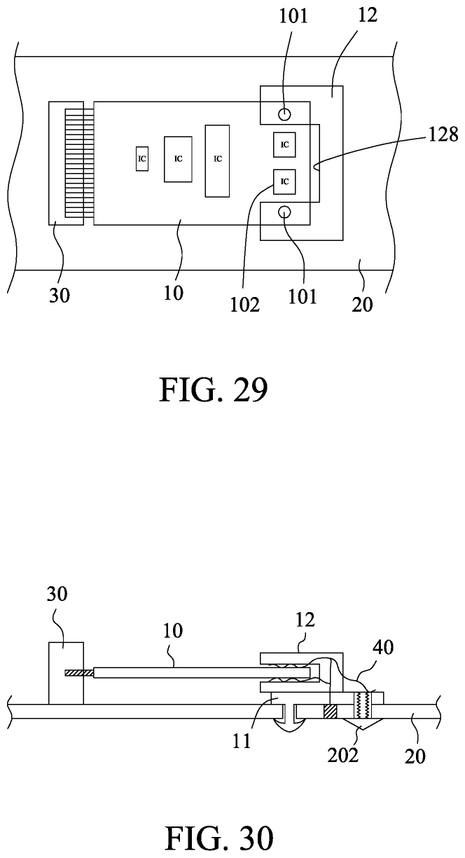

Referring to FIG. 29, in addition to the aforesaid embodiments, in an embodiment of the disclosure, the connecting portion 12 has an avoidance space 128 (or an avoidance region). After the engaged object 10 has been connected to the connector 30, the avoidance space 128 (or the avoidance region) avoids or does not interfere with a raised structure of the engaged object 10, an electronic component of the engaged object 10, an IC component of the engaged object 10, an electrically conductive component of the engaged object 10 or a component 102 of the engaged object 10. Therefore, the present disclosure meets requirements for practical application.

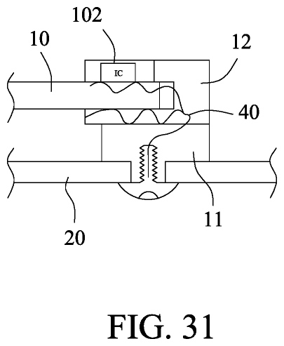

Referring to FIG. 30 and FIG. 31, in addition to the aforesaid embodiments, in an embodiment of the disclosure, the engagement structure 1 has an earthing structure 40 (or an electrically conductive structure). The earthing structure 40 (or the electrically conductive structure) guides or conducts an electric current of the engaged object 10 or the object 20. The earthing structure 40 (or the electrically conductive structure) is a metallic leaf spring, leaf spring, engaging element, threaded element, metallic element or electrically conductive object. Therefore, the present disclosure meets requirements for practical application.

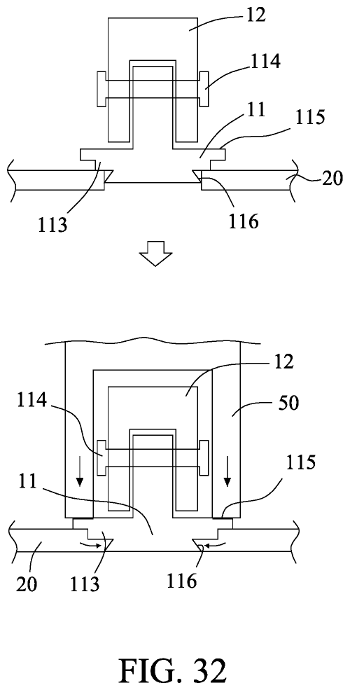

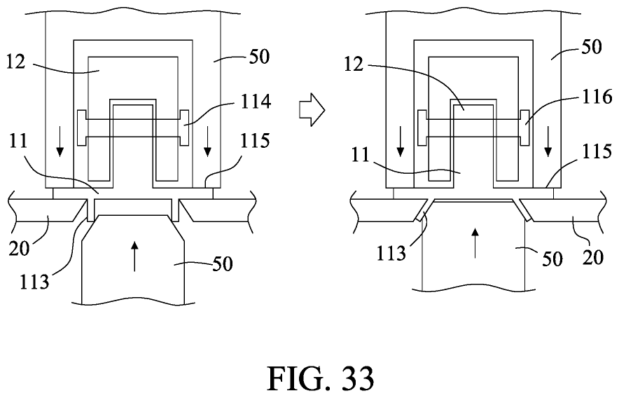

Referring to FIG. 32 and FIG. 33, in addition to the aforesaid embodiments, in an embodiment of the disclosure, the body portion 11 and the connecting portion 12 are movably fitted together by a fitting element 114 (or a bolt element), and the body portion 11 has a shoulder portion 115 adapted to abut against or be pressed against a die 50 such that the raw material of the object 20 flows into or enters the material admission portion 116 of the fitting portion 113 of the body portion 11, allowing the body portion 11 and the object 20 to be firmly coupled together (as shown in FIG. 32).

In addition to the aforesaid embodiments, in an embodiment of the disclosure, the shoulder portion 115 abuts against or is pressed against the die 50 such that the raw material of the object 20 snap-engages with the fitting portion 113 of the body portion 11 to allow the body portion 11 to be expandedly connected to the object 20, allowing the body portion 11 and the object 20 to be firmly coupled together (as shown in FIG. 33).

In addition to the aforesaid embodiments, in an embodiment of the disclosure, the body portion 11, the connecting portion 12 or the object 20 is made of a metallic material, or the body portion 11 is made of a metallic material or plastic material that has undergone heat treatment, or the body portion 11 has higher hardness than the object to allow the raw material of the object 20 to enter or flow into a material admission portion 116 of the body portion 11 when the body portion 11 is riveted to the object 20.

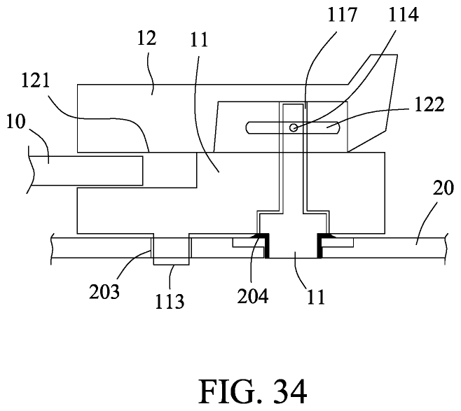

Referring to FIG. 34, in addition to the aforesaid embodiments, in an embodiment of the disclosure, the body portion 11 is in the number of two. One of the body portions 11 and the object 20 are fitted together by soldering, using a solder 204. One of the body portions 11 and the other body portion 11 are penetratedly connected or fitted together through a penetrating hole 117. One of the body portions 11 and the connecting portion 12 are fitted together or bolted together by the fitting element 114, and the fitting element 114 passes through the two body portions 11 and the connecting portion 12 so as to be fitted thereto, allowing the other body portion 11 to be fitted to or to interfere with the engaged object 10. Therefore, the present disclosure meets requirements for practical application.

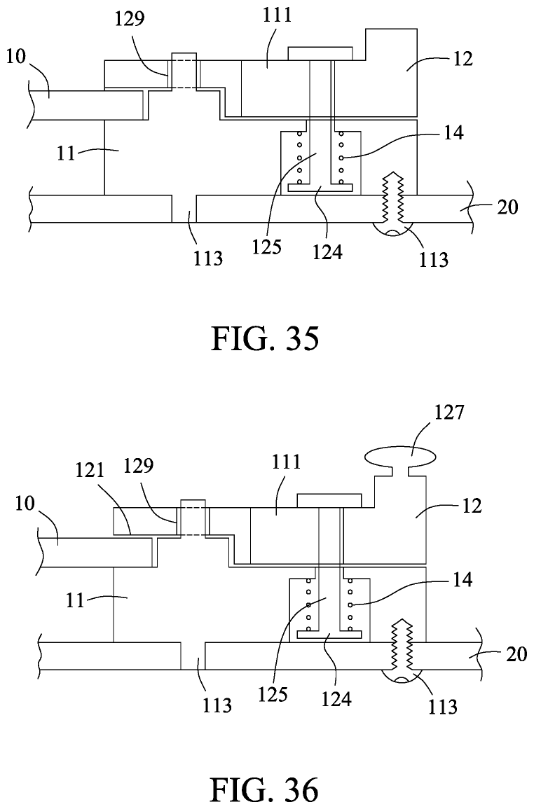

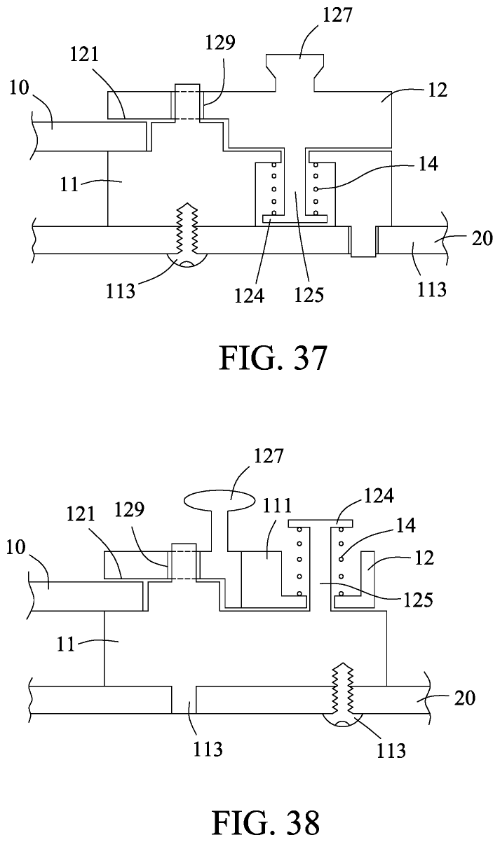

Referring to FIG. 35 through FIG. 38, in addition to the aforesaid embodiments, in an embodiment of the disclosure, the connecting portion 12 has an accommodating portion 129, and the accommodating portion 129 accommodates a corresponding structure of the body portion 11.

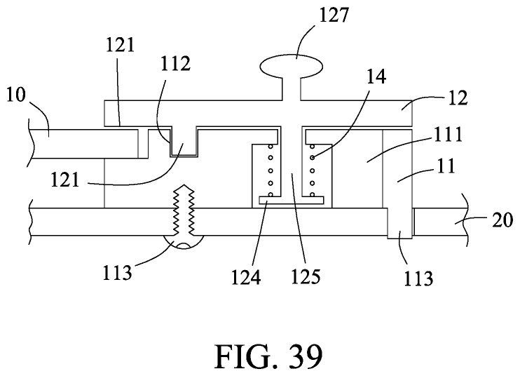

Referring to FIG. 39, in addition to the aforesaid embodiments, in an embodiment of the disclosure, the accommodating portion 112 of the body portion 11 accommodates the limiting portion 121, and the connecting portion 12 has a movement space 111. The connecting portion 12 undergoes axial movement to not only allow the limiting portion 121 to be accommodated in the accommodating portion 112 but also allow the connecting portion 12 to engage with the engaged object 10, allowing at least two objects to be coupled together and separated repeatedly and quickly.

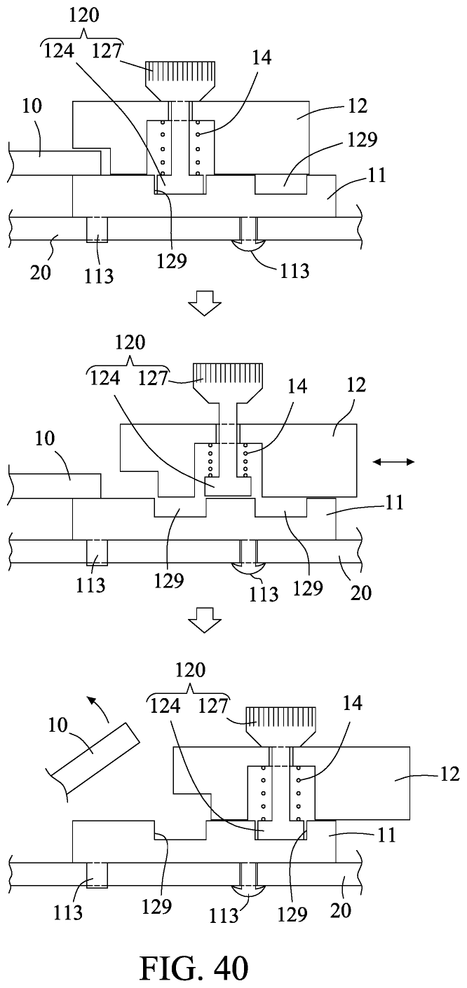

Referring to FIG. 40, in addition to the aforesaid embodiments, in an embodiment of the disclosure, the connecting portion has an engaging portion 120. In this embodiment, the engaging portion 120 is a combination of the blocking portion 124 and the operating portion 127, and the engaging portion 120 snap-engages with one of the accommodating portions 129 of the body portions 11 such that the connecting portion 12 is located at the position at which the connecting portion 12 can engage with the engaged object 10. Alternatively, the engaging portion 120 undergoes axial movement, whereas the connecting portion 12 moves laterally, such that the engaging portion 120 engages with the other accommodating portion 129 of the body portions 11 to allow the connecting portion 12 to be located at the position at which the connecting portion 12 cannot engage with the engaged object 10. Therefore, at least two objects can be coupled together and separated repeatedly and quickly.

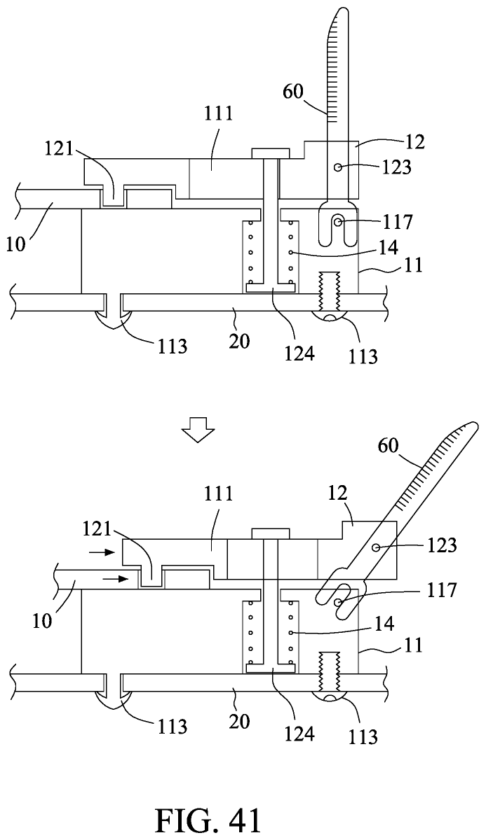

Referring to FIG. 41, in addition to the aforesaid embodiments, the disclosure provides an embodiment in which the connecting portion 12 has an abutting-pushing structure 60. The abutting-pushing structure 60 is movably disposed at the connecting portion 12 through a latch element 123. The body portion 11 has a position-restraining protruding member 117. One end of the abutting-pushing structure 60 is disposed at the position-restraining protruding member 117 to allow the abutting-pushing structure 60 to abut and push the body portion 11 to pull the engaged object 10. Therefore, the disclosure is effective in coupling together and separating at least two objects quickly, allowing the at least two objects to be coupled together and separated repeatedly and quickly.

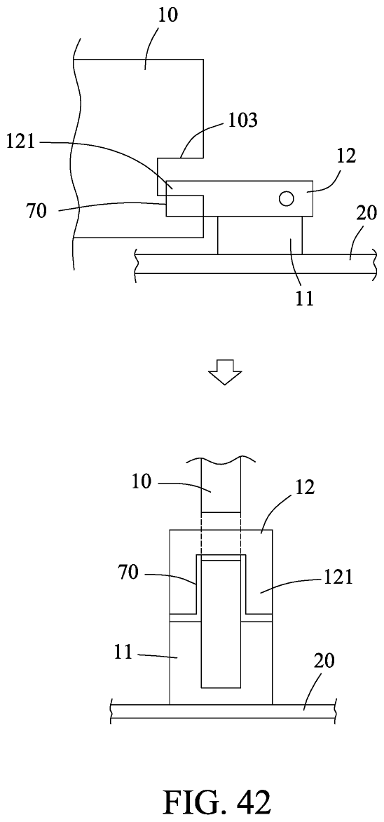

Referring to FIG. 42, in addition to the aforesaid embodiments, the disclosure provides an embodiment in which the connecting portion 12 has a restraining portion 70 for position-restraining the engaged object 10 or for position-restraining two sides of the engaged object 10, or the restraining portion 70 has a part for position-restraining the engaged object 10, and the part has a concave portion 103 (or convex portion) such that the restraining portion 70 restrains the engaged object 10 from above, from below and from two sides through the concave portion 103 (or the convex portion).

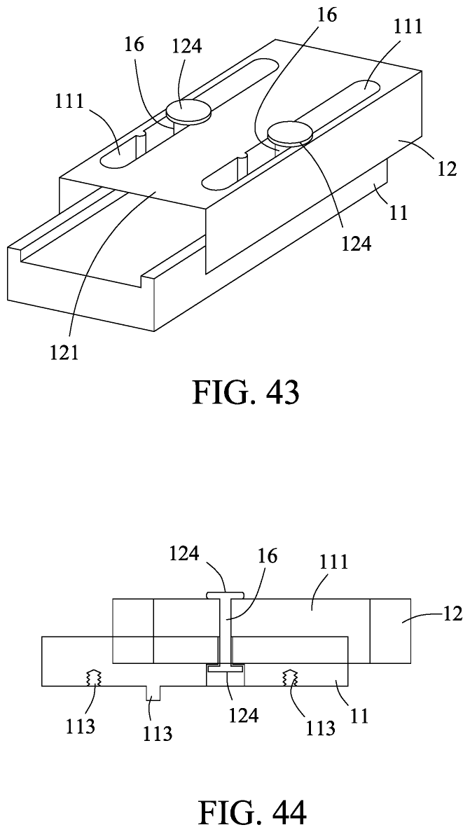

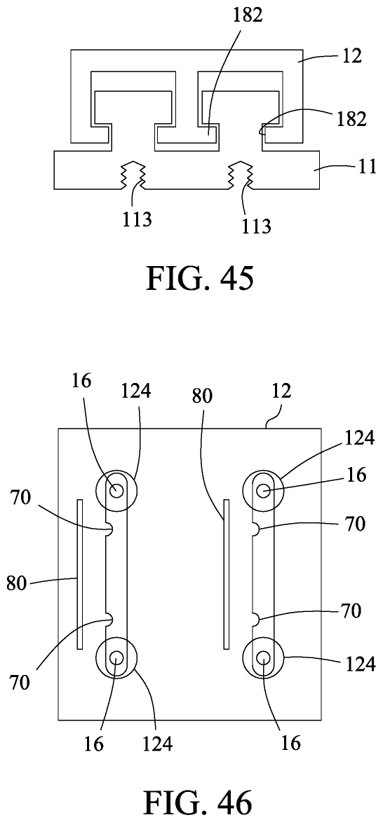

Referring to FIG. 43 through FIG. 46, in addition to the aforesaid embodiments, the disclosure provides an embodiment in which the movement space 111 has a restraining portion 70 for position-restraining a latch element 16, the limiting portion 121 or the connecting portion 12 at an open position or closed position, or the restraining portion 70 is a structure or material capable of undergoing resilient deformation or displacement, or the restraining portion 70 is a plastic material, or the connecting portion 12 has a retraction space 80 (as shown in FIG. 46) for allowing the restraining portion 70 to retract and give way.

In addition to the aforesaid embodiments, in an embodiment of the disclosure, the engaging portion 120 is an engaging element, an engaging element having resilience, an engaging element with a resilient component, an engaging element fitted to a resilient component, or a resilient engaging element. Therefore, the present disclosure meets requirements for practical application.

In conclusion, according to the disclosure, an engagement structure and an engagement method for the same are effective in fitting a body portion to an object and allowing a connecting portion to engage with or disengage from an engaged object such that the at least two objects are coupled together and separated repeatedly and quickly.

The embodiments of the present invention only serve an illustrative purpose but are not restrictive of the claims of the present invention.

What is claimed is:

1. An engagement structure, comprising:
a body portion; and
at least a connecting portion disposed at the body portion, having a limiting portion, and adapted to engage with an engaged object.

2. The engagement structure of claim 1, wherein the body portion is fitted to an object, the object being a circuit board, connector, metallic board, server, chamber, cabinet, storage, computer or plastic board, or the body portion is fitted to the object by engagement, riveting, expanded connection, resilient engagement, soldering, fastening, penetrated connection, magnetic attraction or adhesion, or the body portion and the object are integrally formed, or the body portion has a fitting portion fitted to the object.

3. The engagement structure of claim 1, wherein rotation-proof portions are disposed between the connecting portion and the body portion, or rotation-proof portions are disposed between the body portion and an object, or a resilient component is disposed between the body portion and the connecting portion and adapted to allow the connecting portion to resiliently engage with the engaged object, or the connecting portion has an operating portion adapted to operate the connecting portion, or the body portion and the connecting portion are movably fitted together by an engaging portion, or the engaging portion is a combination of a track and a rail, or the connecting portion moves, slides or undergoes position-restrained movement relative to or snap-engages with the body portion.

4. The engagement structure of claim 1, wherein the body portion and the connecting portion are movably fitted together by an engaging portion, or the body portion and the connecting portion are movably fitted together by a bolt element or a fitting element, or the body portion and the connecting portion are movably fitted together by a resilient arm, or the body portion and the connecting portion are movably fitted together by a plastic engaging portion, or wherein the body portion or the connecting portion has a guiding portion, or the guiding portion guides a resilient component, allowing the connecting portion to resiliently engage with the engaged object, or wherein the body portion or the connecting portion has a blocking portion, or the blocking portion blocks the resilient component between the body portion and the connecting portion, allowing the connecting portion to resiliently engage with the engaged object.

5. The engagement structure of claim 1, wherein the connecting portion snap-engages with two sides of the engaged object, or the connecting portion snap-engages with the two sides, an upper side and a lower side of the engaged object, or the connecting portion snap-engages with the two sides and upper side of the engaged object, or the lower side of the engaged object rests on the body portion, or the connecting portion snap-engages with the two sides and lower side of the engaged object, or the connecting portion snap-engages with the upper side and lower side of the engaged object.

6. The engagement structure of claim 1, wherein the connecting portion is in a number of one or more, each said connecting portion is parallelly fixed to the body portion and moves synchronously therewith, or each said connecting portion is parallelly fixed to the body portion but does not move synchronously therewith, or each said connecting portion is perpendicularly fitted to the body portion and moves synchronously therewith, or each said connecting portion is perpendicularly fitted to the body portion but does not move synchronously therewith, or each said connecting portion is not parallel to the body portion but moves rotatably, or each said connecting portion is parallel to the body portion and moves rotatably.

7. The engagement structure of claim 1, wherein the body portion or the connecting portion has a movement space, or the connecting portion or the body portion has a movement portion, or the movement portion undergoes lateral or axial movement within the movement space, or the limiting portion undergoes axial movement or lateral movement, confining the engaged object to a confinement range of the limiting portion, or the movement portion has a rotation-proof portion for preventing rotation of the movement portion relative to the movement space of the body portion.

8. The engagement structure of claim 1, wherein the body portion or the connecting portion has an accommodating portion adapted to accommodate the engaged object not position-restrained, or accommodate the engaged object position-restrained, or accommodate the limiting portion, or accommodate the limiting portion passing through the engaged object, or accommodate the connecting portion, or accommodate the connecting portion passing through the engaged object, or the connecting portion has an accommodating portion adapted to accommodate a corresponding structure of the body portion.

9. The engagement structure of claim 1, wherein the body portion has a retention portion for position-restraining and retaining the engaged object.

10. The engagement structure of claim 1, wherein the connecting portion is in a number of two or more, or each said connecting portion is perpendicularly fitted to the body portion, or each said connecting portion comprises a multilayer structure, or the body portion is movably fitted to each said connecting portion by a track and a rail, or each said connecting portion moves, slides or undergoes position-restrained movement relative to or snap-engages with the body portion, or a lowest one of the connecting portions has a retention portion adapted to position-restrain and retain the engaged object, or the body portion has a retention portion adapted to position-restrain and retain the engaged object.

11. The engagement structure of claim 1, wherein the connecting portion has an avoidance space or an avoidance region, or the avoidance space or the avoidance region is adapted to avoid or not to interfere with a raised structure of the engaged object, an electronic component of the engaged object, an IC component of the engaged object, an electrically conductive component of the engaged object or a component of the engaged object, or the engagement structure has an earthing structure or an electrically conductive structure, or the earthing structure or the electrically conductive structure is adapted to guide or conduct an electric current of the engaged object or an object, or the earthing structure or the electrically conductive structure is a metallic leaf spring, leaf spring, engaging element, threaded element, metallic element or electrically conductive object.

12. The engagement structure of claim 1, wherein the body portion has a shoulder portion adapted to abut against or to be pressed against such that a raw material of an object flows into or enters a material admission portion of a fitting portion of the body portion, or the shoulder portion is adapted to abut against or to be pressed against such that the raw material of the object snap-engages with a fitting portion of the body portion to allow the body portion to be expandedly connected to the object, or the body portion, the connecting portion or the object is made of a metallic material, or the body portion is made of a metallic material or plastic material having undergone heat treatment, or the body portion has higher hardness than the object, or the raw material of the object enters or flows into a material admission portion of the body portion when the body portion is riveted to the object.

13. The engagement structure of claim 1, wherein the body portion is in a number of two, one of the body portions and an object are fitted together, or one of the body portions and the other body portion are penetratedly connected or fitted together, or one of the body portions and the other body portion are penetratedly connected or fitted together so as to be fitted to or to interfere with the engaged object, or one of the body portions and the other body portion are penetratedly connected or fitted together so as to be fitted to the connecting portion or to be fitted to or bolted to the connecting portion by a fitting element, or a fitting element passes through the two body portions and the connecting portion so as to be fitted thereto.

14. The engagement structure of claim 1, wherein the connecting portion has an engaging portion adapted to snap-engage with the body portion such that the connecting portion is located at a position at which the connecting portion can engage with the engaged object, or the engaging portion is adapted to snap-engage with the body portion such that the connecting portion is located at a position at which the connecting portion cannot engage with the engaged object, or the engaging portion is an engaging element, an engaging element having resilience, an engaging element with a resilient component, an engaging element fitted to a resilient component, or a resilient engaging element.

15. The engagement structure of claim 1, wherein the connecting portion has an abutting-pushing structure adapted to abut and push the body portion to pull the engaged object.

16. The engagement structure of claim 1, wherein the connecting portion has a restraining portion adapted to position-restrain the engaged object, or adapted to position-restrain two sides of the engaged object, or the restraining portion has a part for position-restraining the engaged object, and the part has a concave portion or convex portion, the restraining portion restrains the engaged object from above, from below and from two sides through the concave portion or the convex portion.

17. The engagement structure of claim 1, wherein the body portion or the connecting portion has a movement space, and the movement space has a restraining portion adapted to position-restrain a latch element, the limiting portion or the connecting portion at an open position or closed position, or the restraining portion is a structure or material capable of undergoing resilient deformation or displacement, or the restraining portion is a plastic material, or the connecting portion has a retraction space for allowing the restraining portion to retract and give way.

18. An engagement method for an engagement structure, the engagement structure comprising a body portion and at least one connecting portion, the connecting portion being disposed at the body portion, having a limiting portion, and being adapted to engage with an engaged object, wherein the connecting portion is lifted and then rotatably engages with the engaged object, or the connecting portion rotatably engages with the engaged object, or the connecting portion is resiliently lifted and then rotatably engages with the engaged object, or the connecting portion is lifted and then engages with the engaged object, or the connecting portion is lifted and then laterally engages with the engaged object.

19. An engagement method for an engagement structure, the engagement structure comprising a body portion and at least one connecting portion, the connecting portion being disposed at the body portion, having a limiting portion, and being adapted to engage with an engaged object, wherein the engaged object is fitted to the connector and then engages with the connecting portion, or the engaged object is laterally fitted to the connector and then engages with the connecting portion, or the engaged object is laterally fitted to the connector and then laterally engages with the connecting portion, or the engaged object is rotatably fitted to the connector and then laterally engages with the connecting portion, or the engaged object is rotatably fitted to the connector and then rotatably engages with the connecting portion, or the engaged object is laterally fitted to the connector and then rotatably engages with the connecting portion, or the engaged object is hot-plugged into the connector and then engages with the connecting portion, or the engaged object engages with the connecting portion and then is connected to or hot-plugged into the connector, or the engaged object engages with the connecting portion, and then a user applies a force to the connecting portion or the engaged object, allowing the engaged object to be connected to or hot-plugged into the connector.

20. An engagement method for an engagement structure, the engagement structure comprising a body portion and at least one connecting portion, the connecting portion being disposed at the body portion, having a limiting portion, and being adapted to engage with an engaged object, wherein the body portion has a shoulder portion adapted to abut against or to be pressed against such that a raw material of an object flows into or enters a material admission portion of a fitting portion of the body portion, or the shoulder portion is adapted to abut against or to be pressed against such that the raw material of the object snap-engages with the fitting portion to allow the body portion to be expandedly connected to the object, or allow the body portion to be soldered to the object, or allow the body portion to be fastened to the object.

21. An engagement method for an engagement structure, the engagement structure comprising a body portion and at least one connecting portion, the connecting portion being disposed at the body portion, having a limiting portion, and being adapted to engage with an engaged object, wherein the body portion or the connecting portion has an accommodating portion for accommodating the engaged object not position-restrained, or accommodating the engaged object position-restrained, or accommodating the limiting portion, or accommodating the limiting portion passing through the engaged object, or accommodating the connecting portion, or accommodating the connecting portion passing through the engaged object, or the connecting portion has an accommodating portion for accommodating a corresponding structure of the body portion, or the body portion or the connecting portion has a movement space, or the connecting portion or the body portion has a movement portion, or the movement portion undergoes lateral or axial movement within the movement space, or the limiting portion undergoes axial movement or lateral movement, confining the engaged object to a confinement range of the limiting portion.

22. An engagement method for an engagement structure, the engagement structure comprising a body portion and at least one connecting portion, the connecting portion being disposed at the body portion, having a limiting portion, and being adapted to engage with an engaged object, wherein the connecting portion has an engaging portion adapted to snap-engage with the body portion to allow the connecting portion to be located at a position at which the connecting portion can engage with the engaged object, or the engaging portion snap-engages with the body portion to allow the connecting portion to be located at a position at which the connecting portion cannot engage with the engaged object.
